(19) United States
(12) Patent Application Publication
(10) Pub. No.: US 2020/0152369 A1
(43) Pub. Date: May 14, 2020

(54) PRINTED CIRCUIT BOARD COIL

(71) Applicant: HITACHI-LG DATA STORAGE KOREA, INC., Seoul (KR)

(72) Inventors: Hyunwook Ha, Seoul (KR); Hogil Lee, Seoul (KR)

(73) Assignee: HITACHI-LG DATA STORAGE KOREA, INC., Seoul (KR)

(21) Appl. No.: 16/548,428

(22) Filed: Aug. 22, 2019

(30) Foreign Application Priority Data
Nov. 13, 2018 (KR) 10-2018-0139062

(51) Int. Cl. H01F 27/28; H05K 1/16; H01F 27/29; H01F 38/14; H01F 27/02; H02J 50/10; H02J 50/70

(52) U.S. Cl. CPC H01F 27/2804; H05K 1/165; H01F 27/29; H01F 38/14; H02J 7/025; H01F 27/02; H02J 50/10; H02J 50/70; H01F 2027/2809; H01F 27/288

(57) ABSTRACT

The printed circuit board coil according to the present invention may comprise at least two conductor layers; first and second paths each of which is formed by spirally connecting a plurality of loops; and a first interlayer connector for connecting a second terminal of the first path and a first terminal of the second path. Each loop of a single turn has a distance different from another loop from center and is symmetrical in a plan view. On a plane basis, a first loop of the first path may be arranged to make an angle with a second loop of the second path corresponding to the first loop, or arranged in translation from the second loop.

This application claims the benefit of priority under 35 U.S.C. § 119(a) to Korean Patent Application No. 10-2018-0139062 filed on Nov. 13, 2018, which is incorporated by reference herein in its entirety.

### BACKGROUND

### Field

This disclosure relates to a printed circuit board coil for transmitting or receiving power wirelessly.

### Related Art

With the development of communication and information processing technology, use of smart terminals such as a smart phone, and the like has gradually increased and at present, a charging scheme generally applied to the smart terminals is a scheme that directly connects an adapter connected to a power supply to the smart terminal to charge the smart phone by receiving external power or connects the adapter to the smart terminal through a USB terminal of a host to charge the smart terminal by receiving USB power.

In recent years, in order to reduce inconvenience that the smart terminal needs to be directly connected to the adapter or the host through a connection line, a wireless charging scheme that wirelessly charges a battery by using magnetic coupling without an electrical contact has been gradually applied to the smart terminal.

When electric energy is supplied wirelessly according to an inductive coupling method, a primary coil and a secondary coil are equipped in a transmitting apparatus and a receiving device, respectively, using a Litz wire (or a copper wire) to from a power transfer channel. It may be advantageous in terms of cost to form a coil by a copper wire.

However, there is a limit in reducing the size of the coil due to the thickness of the copper wire. Thus, in recent years, attempts have been made to overcome this limitation by forming a coil pattern in a multilayer spiral path by a PCB (Printed Circuit Board) manufacturing method.

If the coil is manufactured by the PCB method, it is possible to increase the productivity, which is advantageous in lowering the cost compared to the case of manufacturing a coil using a conventional Litz wire, but there is a problem that an AC resistance becomes larger and a Q value is greatly reduced, compared to the Litz wire coil.

### SUMMARY

The present invention has been made in view of such circumstances, and it is an object of the present invention to minimize the reduction of the Q value when forming a coil in the PCB manufacturing method.

A printed circuit board PCB coil according to an embodiment of the present invention may comprise: at least two conductor layers: first and second paths each of which is formed by spirally connecting a plurality of loops, each loop of a single turn having a distance different from another loop from center and being symmetrical in a plan view; and a first interlayer connector for connecting a second terminal of the first path and a first terminal of the second path. On a plane basis, a first loop of the first path may be arranged to make an angle with a second loop of the second path corresponding to the first loop, or arranged in translation from the second loop.

In an embodiment, the single turn loop may be rectangular in the plan view, and at least one of the first loop and the second loop may be arranged to move in parallel in a diagonal direction.

In an embodiment, the single turn loop may be rectangular in the plan view, and the first loop and the second loop may be arranged at 90 degrees to each other.

In an embodiment, the first path may be formed on a first conductor layer and the second path may be formed on a second conductor layer

In an embodiment, the PCB coil may further comprise a plurality of second interlayer connectors for connecting segments of the first path and connecting segments of the second path, the segments of the first path being alternately formed in a first conductor layer and a second conductor layer and the segments of the second path being alternately formed in the first conductor layer and the second conductor layer. The plurality of second interlayer connectors may be arranged symmetrically on the plane basis.

In an embodiment, the second interlayer connectors my have four or more and distances between two adjacent second interlayer connectors may be substantially same

In an embodiment, corresponding second interlayer connectors of at least two loops having different distances from the center may differ in position in a circumferential direction

A wireless power transmitting apparatus according to another embodiment of the present invention may comprise a transmitting coil for changing a magnetic field by an alternating current; a shielding part for limiting propagation of the magnetic field generated in the transmitting coil; and a case for surrounding the transmitting coil and the shielding part. The transmitting coil may comprise first and second paths each of which is formed by spirally connecting a plurality of loops and a first interlayer connector for connecting a second terminal of the first path and a first terminal of the second path. Each loop of a single turn may have a distance different from another loop from center and be symmetrical in a plan view. And, on a plane basis, a first loop of the first path may be arranged to make an angle with a second loop of the second path corresponding to the first loop, or arranged in translation from the second loop.

Accordingly, the Q value of the PCB coil can be increased by canceling the counter electromotive force formed between coil wires due to the proximity effect.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1a and 1b respectively show the bird's-eye view of the conventional PCB coil simulating the Litz wire and the method of changing the positions of traces.

FIG. 2 shows the direction of the counter electromotive force generated when a uniform external magnetic field is applied to a pair of loops of one rotation formed of two traces arranged in parallel with each other,

FIG. 3a illustrates the direction of the counter electromotive force generated when a uniform external magnetic field is applied to a loop pair arranged by moving one loop in parallel in a diagonal direction according to an embodiment of the present invention,

FIG. 3b shows an example in which the counter electromotive forces are canceled by the closed loops formed in the regions surrounded by the loop pair in FIG. 3a,

FIG. 3c shows the PCB coil formed by winding the loop pair of FIG. 3a in a spiral shape,

FIG. 4A shows the direction of the counter electromotive force generated when a uniform external magnetic field is applied to the loop pair of a cross shape in which a rectangle loop is rotated 90 degrees according to another embodiment of the present invention,

FIG. 4b shows an example in which the counter electromotive forces are canceled by the closed loops formed in the regions surrounded by the loop pair in FIG. 4a,

FIG. 4c shows the PCB coil formed by winding the loop pair of FIG. 4a in a spiral shape.

FIG. 5 illustrates the PCB coil by winding in a spiral shape a loop pair arranged by rotating one loop by a predetermined angle with respect to a central axis according, to another embodiment of the present invention.

FIG. 6 shows an example in which the counter electromotive forces due to the magnetic field in a lateral direction are canceled when each loop constituting the loop pair of FIG. 3a is alternately formed in two or more different layers while changing layers using interlayer connectors,

FIG. 7 shows an example of changing the positions of the interlayer connectors in accordance with the radii of the loops when the loop pair of FIG. 6 is spirally wound to form a coil,

FIG. 8 shows an exploded perspective view of a charger equipped with the PCB coil according to the present invention.

### DETAILED DESCRIPTION

Hereinafter, an embodiment of a printed circuit board coil according to the present invention will be described in detail with reference to the accompanying drawings.

When an alternating current flows in a conductor, the current density near the surface of the conductor tends to become larger than that at the center of the conductor, and this phenomenon is referred to as a skin (or surface) effect. With this skin effect, the effective resistance of the conductor increases with the frequency of the AC current. To overcome the skin effect, the coil used in high-frequency applications is wound with the Litz wire which is formed by coating each thin wire with an insulating film and twisting a number of the thin wires together. Since the total surface area of the Litz coil having many thin wires twisted is wider than the surface area of a single wire, the skin effect can be reduced, thereby reducing power loss when transmitting power at a high frequency

However, since in the Litz wire each thin wire is surrounded by the insulator coating and the air layer is formed among the thin wires, the resistance of a coil becomes high and manufacturing cost is expensive. Also, since the thin wires are insulated from each other by the sheath, so there is no path to transfer heat. There is a problem that it grows more than necessary because of the space for insulation.

In order to solve the problem of the Litz wire, a PCB coil which forms a spiral path on a circuit board by a copper foil emerges, and a plurality of layers are formed through vias or interlayer connectors, and there is an attempt to form wire strands, i.e. traces on multiple layers through the vias to increase the number of turns of the coil. However, similarly problems arise such as uneven induction current distribution and uneven inductance distribution occurring in the coil using a single wire.

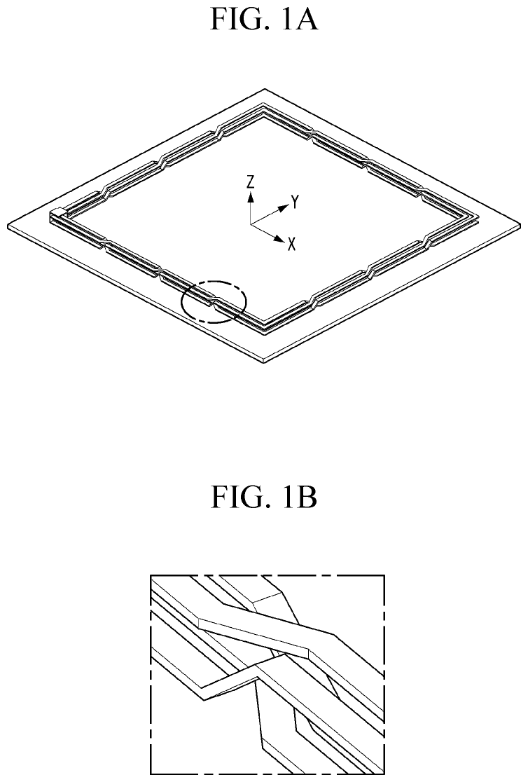

Several methods have been proposed, such as a method of reducing the influence of the skin effect by constituting one turn (or loop) with a plurality of traces in order to improve the disadvantages of PCB coils, or a method in which a plurality of traces are used in one turn by imitating the Litz wire as shown and the positions of the traces are changed as shown in FIG. 1 to reduce both the skin effect and the proximity effect.

However, the first of the above-mentioned methods has a disadvantage in that the Q value may be lowered in a specific situation. For example, in the case of simply configuring the coil with a plurality of traces, a new loop which an eddy current flows through may be formed to result in unnecessary loss, so the Q value may be further reduced.

Also, the second method outlined above requires a large number of vias, which is disadvantageous in that fabrication is difficult and the cost is high. That is, since the traces of a lower layer and a upper layer may overlap when the traces change their layers as shown in FIG. 1b, the shape or arrangement of the traces must be complicated so as not to overlap each other. Also, due to the use of a large number of vias, the resistance of the vias may increase and the cost may increase.

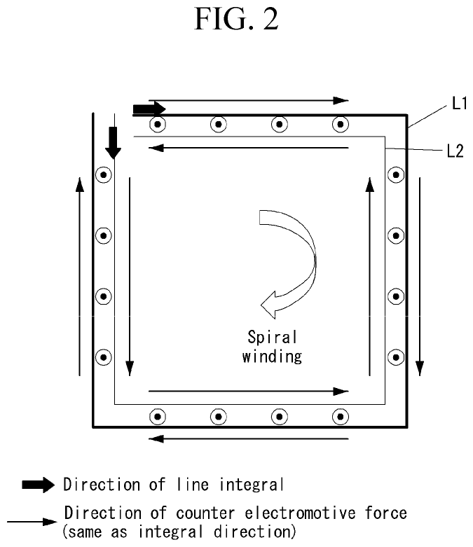

FIG. 2 shows the direction of the counter electromotive force generated when a uniform external magnetic field is applied to a pair of loops of one rotation formed of two traces arranged in parallel with each other. In FIG. 2, the first loop L1 and the second loop L2 forming one loop pair are arranged in parallel to each other in a rectangular shape.

A magnetic field applied to the outside of the first loop L1 and a magnetic field applied to the inside of the second loop L2 generate a counter electromotive force in a same direction to the first loop L1 and the second loop L2 and cancel each other, so they are not subject to consideration.

However, the magnetic field applied between the inside of the first loop L1 and the outside of the second loop L2, i.e. between the first loop L1 and the second loop L2 generate a counter electromotive force in the closed circuit formed by the first loop L1 and the second loop L2.

In FIG. 2, the magnetic field is in a direction from bottom to top perpendicular to the page, so an electric field is generated in the first loop L1 in a clockwise direction and an electric field is generated in the second loop L2 in a counterclockwise direction. The counter electromotive force generated by the changing magnetic field is defined by the following equation.

$$e = - \int \frac{\partial B}{\partial t} \cdot da = ∮ E \cdot dl \qquad [ Equation ]$$

Here, e is the counter electromotive force, B is a magnetic field, a is the area enclosed by the wire, E is an electric field, and l is the length of the wire.

In FIG. 2, the thick arrow indicates the direction of a line integral, the thin arrow indicates the direction of counter electromotive force (or electric field). The direction of the line integral coincides with the direction of the counter electromotive force at all four sides of the first loop L1 so the counter electromotive force due to an external magnetic field is generated in the first loop L1. Similarly, the direction of the line integral coincides with the direction of the counter electromotive force at all four sides of the first loop L2 so the counter electromotive force due to an external magnetic field is generated in the second loop L2.

Namely, when a loop pair is formed by the dual lines in which one or two of the first loop L1 and the second loop L2 is moved in a simple parallel manner as shown in FIG. 2, all the counter electromotive forces due to the external magnetic field are summed in the entire region of the loop, so that a large loop current flows, which leads to an increase in power loss.

In the present invention, one loop is composed of two or more wire strands or traces in order to reduce the skin effect, and the pattern of the traces is made such that the counter electromotive force due to the external magnetic field in the vertical direction can be canceled.

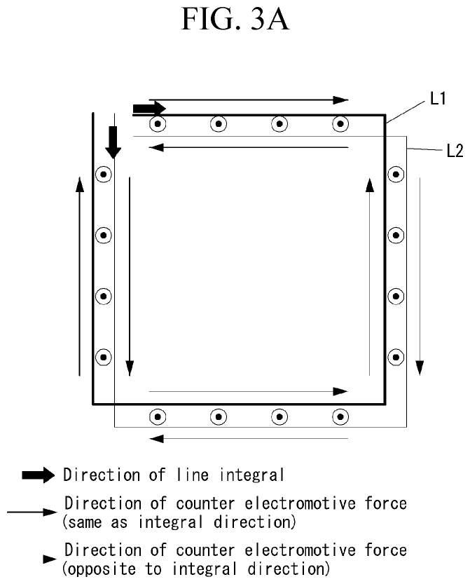

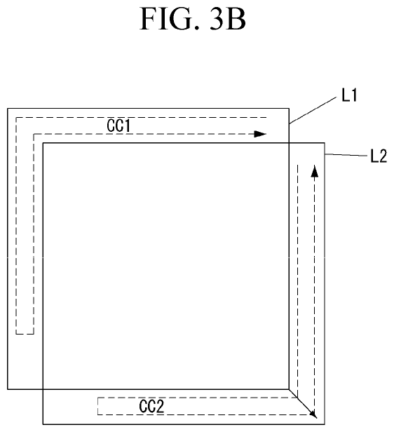

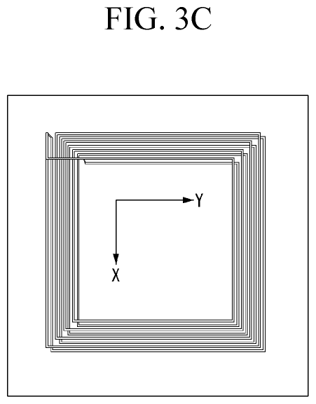

FIG. 3a illustrates the direction of the counter electromotive force generated when a uniform external magnetic field is applied to a loop pair arranged by moving one loop in parallel in a diagonal direction according to an embodiment of the present invention.

In FIG. 3a, the first loop L1 and the second loop L2 of the rectangle shape are staggered. By the second loop L2 is moved in a diagonal direction from the first loop L1 to form a loop fair of the first and second loops L1 and L2.

As described with reference to FIG. 2, only the magnetic field applied between the first loop L1 and the second loop L2 generates a counter electromotive force in the first loop L1 and the second loop L2, so it is not necessary to consider the magnetic fields of the outer side and the inner side of both the first loop L1 and the second loop L2. Since the magnetic field is directed upward from below, a counter electromotive force is generated clockwise in the wire surrounding the magnetic field.

In the first loop L1, the direction of the line integral and the direction of the counter electromotive force coincide with each other on the left side and the upper side, and the direction of the line integral and the direction of the counter electromotive force are opposite to each other on the lower side and the right side. That is, the counter electromotive forces generated from the left side and the right side are equal in magnitude and opposite in sign so cancel each other, and the counter electromotive forces generated in the upper side and the lower side are equal in magnitude and opposite in sign so cancel each other. As a result, the loop current flowing through the first loop L1 due to the magnetic field is absent or less, which results no loss or reduced loss.

Similarly, in the second loop L2, the direction of the line integral and the direction of the counter electromotive force coincide with each other on the left side and the upper side, and the direction of the line integral and the direction of the counter electromotive force are opposite to each other on the lower side and the right side. That is, the counter electromotive forces generated from the left side and the right side cancel each other, and the counter electromotive forces generated in the upper side and the lower side cancel each other, so the loop current flowing through the second loop L2 due to the magnetic field is absent or less, which results no loss or reduced loss

By arranging the first loop L1 and the second loop L2 in a staggered arrangement, the paths in which the directions of an integral path and a counter electromotive force are opposite to each other are generated, and the sum of the lengths of the paths can be equal to the sum of the lengths of the paths in which the directions of an integral path and a counter electromotive force are same. So that the counter electromotive forces generated by the magnetic field may be canceled or minimized.

FIG. 3b shows an example in which the counter electromotive force is canceled by the closed loops formed in the regions surrounded by the loop pair in FIG. 3a.

In FIG. 3b, a first closed circuit CC1 is formed by the upper side and the left side of the first loop L1 and the second loop L2, and a second closed circuit CC2 is formed by the lower side and the right side of the first loop L1 and the second loop L2. The counter electromotive force generated in the first closed circuit CC1 can be canceled by the counter electromotive force generated in the second closed circuit CC2.

FIG. 3c shows the PCB coil formed by winding the loop pair of FIG. 3a in a spiral shape. A first helical path spirally connecting a plurality of first loops having different distances from the center is formed in a first conductor layer of a printed circuit board PCB, and a second helical path spirally connecting a plurality of second loops having different distances from the center is formed in a second conductor layer of the PCB, thereby forms a PCB coil.

By connecting the second terminal which is located at the outermost circumference in the first helical path (or the first spiral path) to the first terminal located at the innermost circumference in the second spiral path (or the second spiral path), the current for power supply or power reception may flow through the first helical path and the second helical path in a same direction with respect to the circumferential direction. Since the first helical path and the second helical path are respectively formed in the first conductor layer and the second conductor layer, a via or interlayer connector is formed between the first conductor layer and the second conductor layer for connecting the second terminal of the first helical path and the first terminal of the second helical path. Since the via is formed vertically and the positions of the second terminal of the first helical path and the first terminal of the second helical path do not coincide with each other on a plane basis, a line extending from the second terminal of the first helical path to the position corresponding to the first terminal of the second helical path may be formed.

As described above, the first loop and the second loop having the same distance from the center are formed as a loop pair and arranged to be staggered so that counter electromotive forces generated by an external magnetic field may be reduced.

For reference, the magnetic field applied between two loops of a loop pair corresponds to the magnetic field formed when current is applied to another loop formed in a same conductor layer or another conductor layer.

The printed circuit board PCB on which the coil of the present invention is formed is composed of two or more conductor layers and insulating layers between two adjacent conductor layers. Patterns of different conductor layers may be connected to each other through interlayer connectors. The coil of the present invention may be formed of a flexible PCB.

In FIG. 3, a plurality of loops of three or more are formed in a plurality of conductor layers of three or more, and are arranged in a staggered manner in a group, and a loop pair constituted by two loops selected from them may suppress the generation of counter electromotive forces by an external magnetic field.

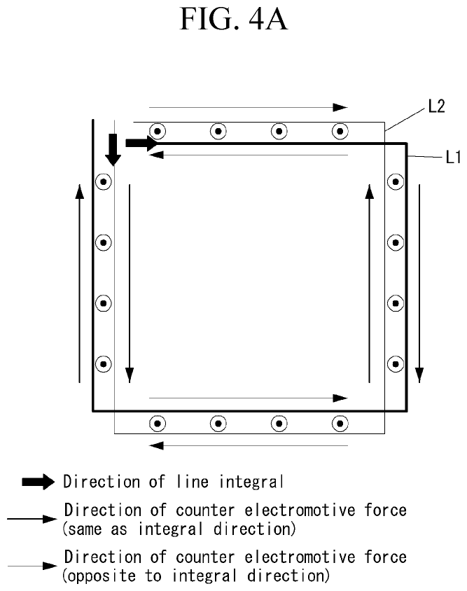

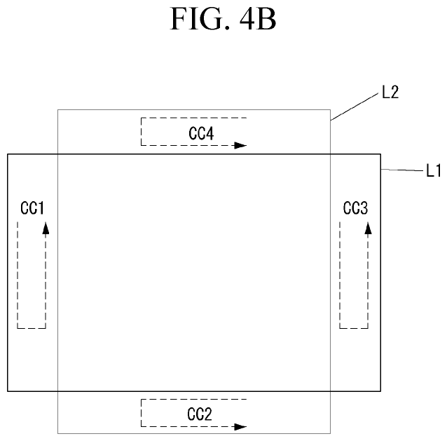

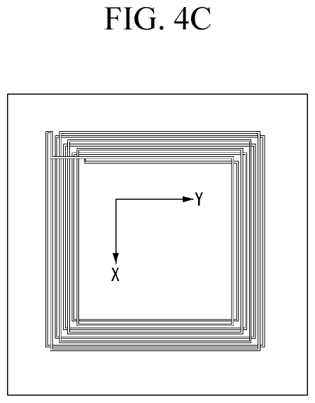

FIG. 4A shows the direction of the counter electromotive force generated when a uniform external magnetic field is applied to the loop pair of a cross shape in which a rectangle loop is rotated 90 degrees according to another embodiment of the present invention.

The first loop L1 has a rectangular shape elongated in the transverse direction and the second loop L2 has a rectangular shape elongated in the longitudinal direction. When the first loop L1 and the second loop L2 are arranged to overlap with each other, a cross shape is formed. When the first loop L1 is rotated 90 degrees, it becomes the second loop L2.

The right side and the left side of the first loop L1 are located outside the second loop L2 and the upper side and the lower side of the second loop L2 are located outside the first loop L1.

In the first loop L1, the direction of the line integral and the direction of the counter electromotive force coincide with each other on the left side and the right side outside the second loop L2, and the direction of the line integral and the direction of the counter electromotive force are opposite to each other on the lower side and the upper side inside the second loop L2. Therefore, when the line integral is made along the first loop L1, the sum of the lengths of the sides coinciding with the direction of the counter electromotive force and the sum of the lengths of the sides opposite to the direction of the counter electromotive force are almost same, so the counter electromotive force is hardly generated in the first loop L1 due to the magnetic field applied between the first loop L1 and the second loop L2.

Similarly, in the second loop L2, the direction of the line integral and the direction of the counter electromotive force are opposite to each other on the lower side and the upper side outside the first loop L1, and the direction of the line integral and the direction of the counter electromotive force coincide with each other on the left side and the right side inside the first loop L1. Therefore, when the line integral is made along the second loop L2, the sum of the lengths of the sides coinciding with the direction of the counter electromotive force and the sum of the lengths of the sides opposite to the direction of the counter electromotive force are almost same, so the counter electromotive force is hardly generated in the first loop L2 due to the magnetic field applied between the first loop L1 and the second loop L2.

FIG. 4b shows an example in which the counter electromotive forces are canceled by the closed loops formed in the regions surrounded by the loop pair in FIG. 4a.

In FIG. 4b, the first closed circuit CC1 is formed by the left sides of the first loop L1 and the second loop L2, the second closed circuit CC2 is formed by the lower sides of the first loop L1 and the second loop L2, the third closed circuit CC3 is formed by the right sides of the first loop L1 and the second loop L2, and the fourth closed circuit CC4 is formed by the upper sides of the first loop L1 and the second loop L2. The counter electromotive force generated in the first closed circuit CC1 may be canceled by the counter electromotive force generated in the second closed circuit CC2 and the counter electromotive force generated in the third closed circuit CC3 may be canceled by the counter electromotive force generated in the fourth closed circuit CC4.

FIG. 4c shows the PCB coil formed by winding the loop pair of FIG. 4a in a spiral shape. A first helical path spirally connecting a plurality of first loops which are in the form of the rectangle longer in the transverse direction and have different distances from the center is formed in a first conductor layer of a printed circuit board PCB, and a second helical path spirally connecting a plurality of second loops which are in the form of the rectangle longer in the longitudinal direction and have different distances from the center is formed in a second conductor layer of the PCB, thereby forms the PCB coil in which a plurality of cross-shaped loop pairs are formed

As shown in FIGS. 3a and 4a, when the first loop L1 and the second loop L2 form one loop pair, if the sum of the lengths of the sides of the first loop L1 outside the second loop L2 and the sum of the lengths of the sides of the first loop L1 inside the second loop L2 become same and the sum of the lengths of the sides of the second loop L2 outside the first loop L1 and the sum of the lengths of the sides of the second loop L2 inside the first loop L1 become same, the generation of the counter electromotive force by the magnetic field generated by the another loop may be minimized.

In FIG. 4, the second loop L2 coinciding with the first loop LI of the rectangular shape rotated by 90 degrees is arranged in a cross shape together with the first loop L1. It is possible to prevent the counter electromotive force from being generated by the magnetic field even if the second loop L2 is rotated at an arbitrary angle instead of 90 degrees.

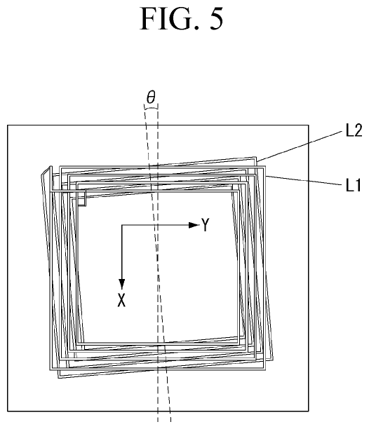

FIG. 5 illustrates the PCB coil by winding in a spiral shape a loop pair arranged by rotating one loop by a predetermined angle with respect to a central axis according to another embodiment of the present invention.

If the second loop L2 is arranged by rotating the first loop L1 by a predetermined angle θ with respect to the center of the loop, similar to the embodiment of FIG. 4, the length of the relatively outer sides and the length of the relatively inner sides become almost same, so it is possible to minimize the occurrence of the counter electromotive force by the magnetic field generated by another loop.

If the loop pair is line-symmetric or point-symmetric with respect to the center, even if one loop of the loop pair is rotated by an arbitrary angle, the length of the sides on the inner side than the other loop of the loop pair and the length of the sides on the outer side than the other loop of the loop pair are equal to each other, so that the generation of the counter electromotive force may be minimized.

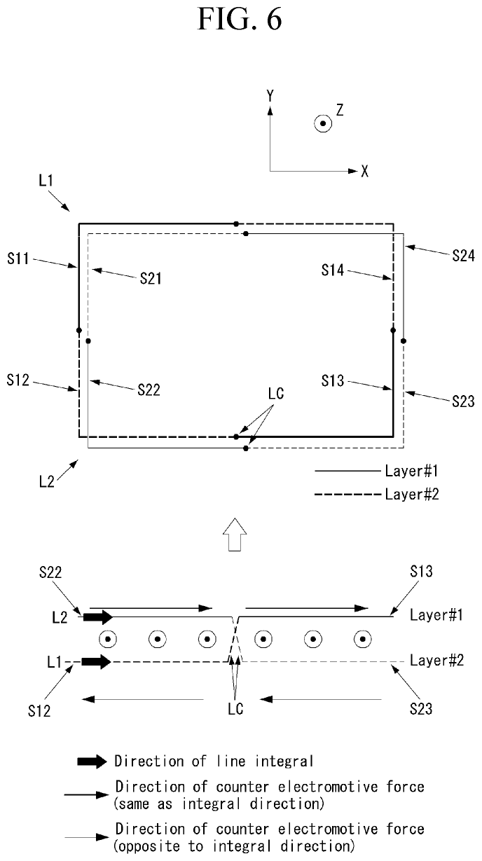

FIG. 6 shows an example in which the counter electromotive forces due to the magnetic field in a lateral direction are canceled when each loop constituting the loop pair of FIG. 3a is alternately formed in two or more different layers while changing layers using interlayer connectors

While the embodiments of FIGS. 3 to 5 are intended to minimize the counter electromotive force generated by the magnetic field traveling in the direction perpendicular to the page (Z direction) FIG. 6 is for minimizing the counter electromotive force due to the magnetic field (X direction or Y direction) traveling to the side surface.

The figure above in FIG. 6 is a plan view showing a loop pair in which one of the first loop L1 and the second loop L2 is shifted by a predetermined distance in a diagonal direction and staggered from each other, and the figure below shows the loop pair looking the lower side from a lateral direction or a side surface.

In the embodiments of FIGS. 3 to 5, it is assumed that the first loop LI is formed on the first conductor layer or the first layer Layer #1 of the printed circuit board PCB and the second loop L2 is formed on the second conductor layer or the second layer Layer #2.

In order to cancel the counter electromotive force due to the magnetic field in the lateral direction, each of the first loop L1 and the second loop L2 is not continuously formed on a same layer, and the first loop L1 and the second loop L2 are alternately formed on the first layer and the second layer while proceeding in the circumferential direction. Vias or interlayer connectors are employed for layer crossing.

In FIG. 6, a solid line means that a segment forming a loop is formed in the first layer Layer #1, and a dotted line means that a segment is formed in the second layer Layer #2.

In the first loop L1 of FIG. 6, when advancing in a counter clockwise, a first segment S11 formed on the upper left of the first layer Layer #1 is interlayer-moved to the second layer Layer #2 by the interlayer connector LC in the middle of the left side to be connected to a second segment S12 formed on the lower left of the second layer Layer #2. The second segment S 12 formed on the lower left of the second layer Layer #2 is interlayer-moved to the first layer Layer #1 by the interlayer connector LC in the middle of the lower side to be connected to a third segment S13 formed on the lower right of the first layer Layer #1. The third segment S13 formed on the lower right of the first layer Layer #1 is interlayer-moved to the second layer Layer #2 by the interlayer connector LC in the middle of the right side to be connected to a fourth segment S14 formed on the right left of the second layer Layer #4. The fourth segment S14 formed on the upper right of the second layer Layer #2 is interlayer-moved to the first layer Layer #1 by the interlayer connector LC in the middle of the upper side to be connected to a first segment S11 formed on the upper left of the next first loop which is farther from the center than the first loop L1.

Similarly, in the second loop L2 of FIG. 6, when advancing in the counter clockwise, a first segment S21 formed on the upper left of the second layer Layer #2 is interlayer-moved to the first layer Layer #1 by the interlayer connector LC in the middle of the left side to be connected to a second segment S22 formed on the lower left of the first layer Layer #1. The second segment S22 formed on the lower left of the first layer Layer #1 is interlayer-moved to the second layer Layer #2 by the interlayer connector LC in the middle of the lower side to be connected to a third segment S23 formed on the lower right of the second layer Layer #2. The third segment S23 formed on the lower right of the second layer Layer #2 is interlayer-moved to the first layer Layer #1 by the interlayer connector LC in the middle of the right side to be connected to a fourth segment S24 formed on the right left of the first layer Layer 41. The fourth segment S24 formed on the upper right of the first layer Layer #1 is interlayer-moved to the second layer Layer #2 by the interlayer connector LC in the middle of the upper side to be connected to a first segment S21 formed on the upper left of the next second loop which is farther from the center than the second loop L2.

In the below figure in FIG. 6 looking the lower side of the loop pair from the side surface, a magnetic field is directed from the center of the loop to the outside (−Y direction). Since the direction of a line integral and the direction of a counter electromotive force are opposite to each other in the second segment S12 of the first loop L1 formed on the second layer Layer #2 and the direction of a line integral and the direction of a counter electromotive force are same in the third segment S13 of the first loop L1 formed on the first layer Layer 1, the counter electromotive forces generated at the lower side of the first loop L1 are canceled by the magnetic field directed from the center to the lower side.

Similarly, since the direction of a line integral and the direction of a counter electromotive force are same in the second segment S22 of the second loop L2 formed on the first layer Layer #1 and the direction of a line integral and the direction of a counter electromotive force are opposite to each other in the third segment S23 of the second loop L2 formed on the second layer Layer #2, the counter electromotive forces generated at the lower side of the second loop L 2 are canceled by the magnetic field directed from the center to the lower side.

Similarly, with respect to the upper side of the first loop L1 and the upper side of the second loop L2 in relation to the magnetic field in the Y direction, since there are two or more segments formed in different layers by the interlayer connectors LC formed in the middle of the upper sides, the directions of the line integral and the counter electromotive force are same in one segment and the directions of the line integral and the counter electromotive force are opposite to each other in the other segment, so that the counter-electromotive forces may be canceled.

Although the interlayer connectors are shown as being located at the center of the side in FIG. 6, if the interlayer connectors are arranged in point symmetry with respect to the center of the loop, the counter electromotive forces generated at each side may not be canceled out, but the sum of the counter electromotive forces generated at the corresponding sides may cancel each other.

With respect to the magnetic field in the right or left direction from the center of the loop, that is the magnet field of the X directional component, if the interlayer connectors are provided in point symmetry, the counter electromotive forces generated on the right and left sides of the loop may cancel each other.

FIG. 6 shows a case where the loop is rectangular, but if the loop is circular and four or more even-numbered interlayer connectors are arranged in point symmetry in each loop, the counter electromotive force due to the magnetic field in the lateral direction may be minimized. If the interlayer connectors are disposed at substantially equal intervals along the circumference of the loop, it may be more advantageous to minimize the counter electromotive force.

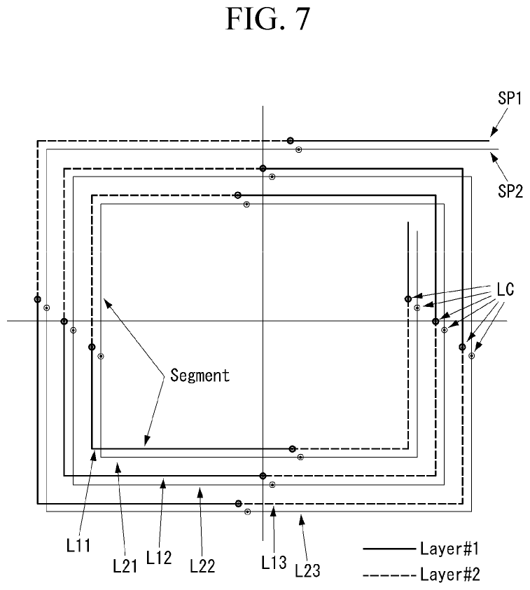

FIG. 7 shows an example of changing the positions of the interlayer connectors in accordance with the radii of the loops when the loop pair of FIG. 6 is spirally wound to form a coil.

In FIG. 7. rectangular shaped loops gradually increasing in size are sequentially connected to form a spiral trajectory, that is the spiral paths SP1 and SP2 on the two or more layers.

In FIG. 7, the first spiral path SP1 is formed by connecting three loops L11, L12 and L13 and the second spiral path SP2 is formed by connecting three loops L21, L22 and L23. The first to third loops L11, L12 and L13 of the first spiral path SP1 correspond to the first to third loops L21, L22 and L23 of the second spiral path SP2, respectively. Two corresponding loops are staggered apart from each other by a predetermined distance in the diagonal direction.

Each loop includes two segments in the first layer Layer #1 and two segments in the second layer Layer #2. In each loop, the segments interlayer-move at the interlayer connectors LC so that the path alternates between the first layer #1 and the second layer Layer #2. When a segment of one loop in two corresponding loops is formed in the first layer Layer #1, the corresponding segment of the other loop may be formed in the second layer Layer #2.

In each loop, one interlayer connector LC is formed on each of four sides. However, the present invention is not limited to this, and a plurality of interlayer connectors may be formed in line symmetry or point symmetry with each other. The intervals between interlayer connectors in the loop may be substantially same. Or, because respective loops are connected to each other to form a spiral path so each loop is not closed, even if the positions of the interlayer connectors are same in the circumferential direction or in point symmetry. the intervals between them are not equal. but they may be substantially same in a same loop.

In FIG. 7, an interlayer connector is formed in the center of each side of the second loop L12 of the first spiral path SP1, with respect to the center of the first spiral path SP1, interlayer connectors may be formed on respective sides of the first loop L11 and the third loop L13 at positions spaced symmetrically from each other at the center instead of the center.

That is, the positions of the corresponding interlayer connectors in the circumferential direction may be different from each other in loops having different radii. In the left sides of the loops in FIG. 7, the interlayer connector of the second loop L12 in the middle in the radial direction may be located at a position further advanced clockwise than the interlayer connector of the innermost first loop L11, and the interlayer connector of the outer most third loop L13 may be located at a position further advanced clockwise than the interlayer connector of the central second loop L12.

While the embodiments of FIGS. 3 to 7 form a single turn of the spiral path in a rectangular loop, the present invention is not limited to this. The plane shape of the loop may be a polygon having a symmetrical shape, for example, a triangle, a rectangle, a pentagon, a hexagon, an octagon, an ellipse, or a circle.

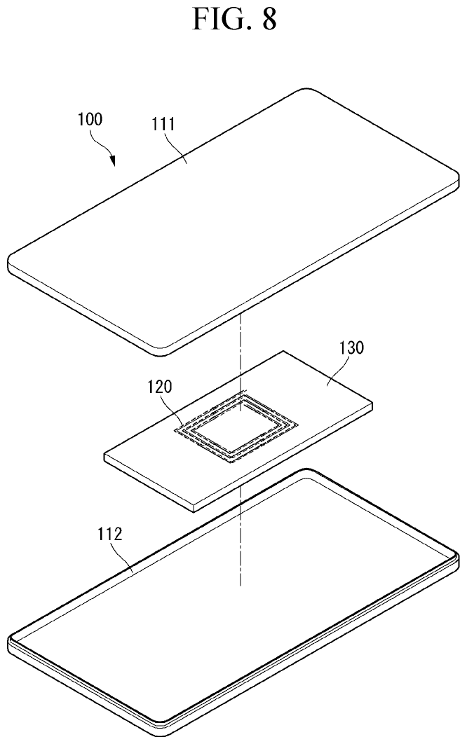

FIG. 8 shows an exploded perspective view of a charger equipped with the PCB coil according to the present invention.

The charger 100 in FIG. 8 may include a wireless power transmitting apparatus that provides inductive power. On the upper surface of the charger, an electronic device including the power receiving device to be charged is placed, and a seating, surface having an operation area may be formed. When the electronic device is placed on the seating surface, the charger may detect this and start wireless charging.

In the charger 100, the PCB transmitting coil 120 shown in FIG. 7 may be mounted between a front case 111 and a rear case 112, and a shielding part 130 may be formed under the transmitting coil 120. That is, the shielding part 130 may be formed between the rear case 112 and the transmitting coil 120 of the charger 100 and may be formed so as to at least partially exceed the outer periphery of the transmitting coil 120.

The shielding part 130 may prevent elements such as a microprocessor, a memory, and the like formed on a circuit board (not shown) from being affected by electromagnetic effects due to the operation of the transmitting coil 120, or prevent the transmitting coil 120 from being affected by the electromagnetic effects due to the operations of the elements mounted on the circuit board. The shielding part 130 may be made of stainless steel or titanium which does not require plating.

The charger 100 may have a structure in which a power conversion unit including a transmitting coil, a communication unit, a control unit, a power supply unit, and the like are provided in one body. Or, the charger 100 may a structure in which a first body to which the transmitting coil 120 and the shielding part 130 are mounted is separated from a second body including, the power conversion unit, the communication unit, the control unit, the power supply unit, and the like for controlling the operation of the transmitting coil 120.

And, the body of the charger 100 may be provided with an output unit such as a display or a speaker, a user input unit, a socket for supplying power, or an interface for coupling external equipment. The display may be formed on the upper surface of the front case 111, and the user input unit, the socket, or the like may be disposed on the side surface of the body.

Throughout the description, it should be understood by those skilled in the art that various changes and modifications are possible without departing from the technical principles of the present invention. Therefore, the technical scope of the present invention is not limited to the detailed descriptions in this specification but should be defined by the scope of the appended claims.

What is claimed is:

1. A printed circuit board PCB coil, comprising:
at least two conductor layers;
first and second paths each of which is formed by spirally connecting a plurality of loops, each loop of a single turn having a distance different from another loop from center and being symmetrical in a plan view; and
a first interlayer connector for connecting a second terminal of the first path and a first terminal of the second path,
wherein on a plane basis, a first loop of the first path is arranged to make an angle with a second loop of the second path corresponding to the first loop, or arranged in translation from the second loop.

2. The PCB coil of claim 1, wherein the single turn loop is rectangular in the plan view, and at least one of the first loop and the second loop is arranged to move in parallel in a diagonal direction.

3. The PCB coil of claim 1, wherein the single turn loop is rectangular in the plan view. and the first loop and the second loop are arranged at 90 degrees to each other.

4. The PCB coil of claim 1 wherein the first path is formed on a first conductor layer and the second path is formed on a second conductor layer.

5. The PCB coil of claim 1, further comprising:
a plurality of second interlayer connectors for connecting segments of the first path and connecting segments of the second path, the segments of the first path being alternately formed in a first conductor layer and a second conductor layer and the segments of the second path being alternately formed in the first conductor layer and the second conductor layer,
wherein the plurality of second interlayer connectors are arranged symmetrically on the plane basis.

6. The PCB coil of claim 5, wherein the second interlayer connectors have four or more and distances between two adjacent second interlayer connectors are substantially same.

7. The PCB coil of claim 6, wherein corresponding second interlayer connectors of at least two loops having different distances from the center differ in position in a circumferential direction.

8. A wireless power transmitting apparatus, comprising:
a transmitting coil for changing a magnetic field by an alternating current;
a shielding part for limiting propagation of the magnetic field generated in the transmitting coil; and
a case for surrounding the transmitting coil and the shielding part,
wherein the transmitting coil comprises first and second paths each of which is formed by spirally connecting a plurality of loops and a first interlayer connector for connecting a second terminal of the first path and a first terminal of the second path, each loop of a single turn having a distance different from another loop from center and being symmetrical in a plan view, and
wherein on a plane basis, a first loop of the first path is arranged to make an angle with a second loop of the second path corresponding to the first loop, or arranged in translation from the second loop.
